(19) United States
(12) Patent Application Publication
(10) Pub. No.: US 2012/0315501 A1
(43) Pub. Date: Dec. 13, 2012

(54) COATED ARTICLE AND METHOD FOR MAKING SAME

(75) Inventors: HUANN-WU CHIANG, Tu-Cheng (TW); CHENG-SHI CHEN, Tu-Cheng (TW); YING-YING WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen (CN)

(21) Appl. No.: 13/238,157

(22) Filed: Sep. 21, 2011

(30) Foreign Application Priority Data
Jun. 13, 2011 (CN) 201110157289.4

(51) Int. Cl. B32B 15/04; B32B 5/00; C23C 14/35; B32B 15/08; C23C 16/22; C23C 16/06; B32B 18/00; B32B 3/00

(52) U.S. Cl. 428/649; 428/469; 428/472.2; 428/336; 428/141; 428/653; 428/654; 428/650; 428/659; 427/250; 204/192.15

(57) ABSTRACT

A coated article is provided. A coated article includes a substrate having a color layer and a ceramic layer formed thereon, and in that order. The color layer substantially comprises a material elected from the group consisting of aluminum, aluminum alloy, zinc, and zinc alloy. The ceramic layer substantially consists of substance M, elemental O, and elemental N, wherein M is elemental Al or elemental Zn.

### CROSS-REFERENCE TO RELATED APPLICATIONS

This application is one of the six related co-pending U.S. patent applications listed below. All listed applications have the same assignee. The disclosure of each of the listed applications is incorporated by reference into the other listed applications.

| Attorney | | |
|---|---|---|
| Docket No. | Title | Inventors |
| US 40037 | COATED ARTICLE AND METHOD | HUANN-WU |
| | FOR MAKING SAME | CHIANG et al. |
| US 40225 | COATED ARTICLE AND METHOD | HUANN-WU |
| | FOR MAKING SAME | CHIANG et al. |
| US 40740 | COATED ARTICLE AND METHOD | HSIN-PEI |
| | FOR MAKING SAME | CHANG et al. |
| US 40741 | COATED ARTICLE AND METHOD | WEN-RONG |
| | FOR MAKING SAME | CHEN et al. |
| US 40742 | COATED ARTICLE AND METHOD | HSIN-PEI |
| | FOR MAKING SAME | CHANG et al. |
| US 40968 | COATED ARTICLE AND METHOD | WEN-RONG |
| | FOR MAKING SAME | CHEN et al. |

### BACKGROUND

1. Technical Field

The exemplary disclosure generally relates to coated articles and a method for manufacturing the coated articles, particularly coated articles having a bone china-like appearance and a method for making the coated articles.

2. Description of Related Art

Typically, vacuum deposition, anodic treatment and spray painting can be used to form a thin film or coating on housings of portable electronic devices, to improve appearance of housings. The housings may be presented with a colorful appearance, but cannot present a high level of whiteness, brightness, and translucent appearance such as bone china.

The traditional formulation for bone china contains about 25% kaolin, 25% Cornish stone and 50% bone ash. The bone ash for the bone china may be made from cattle bones having a lower amount of iron. However, the expensive cattle bones, the complex manufacturing process, and the low yielding rate make bone china very expensive and thus not economically feasible in the construction of housings of portable electronic devices.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary coated article and method for manufacturing the coated article. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of the present coated article.

FIG. 2 is a photograph of a field emission stereoscan (100,000× magnified) of a ceramic layer of an exemplary coated article.

FIG. 3 is a schematic view of a vacuum sputtering machine for manufacturing the coated article of FIG. 1.

### DETAILED DESCRIPTION

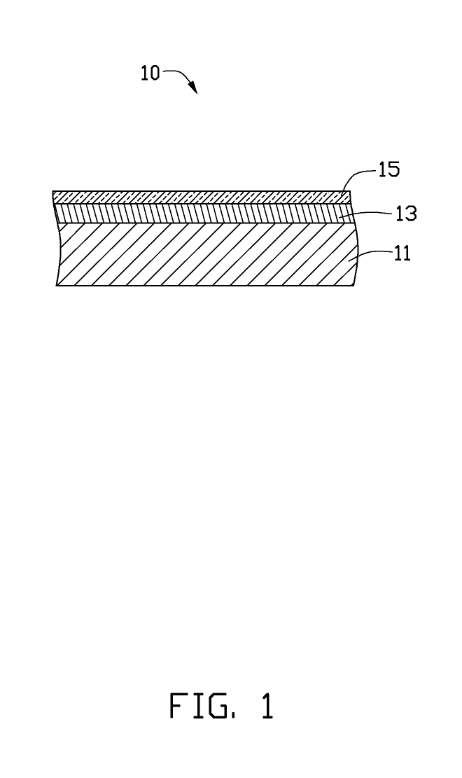

FIG. 1 shows an exemplary embodiment of a coated article. The coated article 10 includes a substrate 11, a color layer 13 formed on the substrate 11, and a ceramic layer 15 formed on the color layer 13. The coated article 10 may be a housing of mobile phone, personal digital apparatus (PDA), notebook computer, portable music player, GPS navigator, or digital camera.

The substrate 11 may be made of metal, such as stainless steel, aluminum (Al), Al alloy, magnesium (Mg), or Mg alloy. The substrate 11 may also be made of nonmetal materials, such as plastic.

The color layer 13 may substantially comprise a material selected from the group consisting of Al, Al alloy, zinc (Zn), and Zn alloy. The Al alloy or Zn alloy, has a mass percentage of about 85%-90% of Al or Zn. The color layer 13 has an L* value between about 88 to about 93 in the CIE L*a*b* (CIE LAB) color space, so the color layer 13 is white and is presented with a china-like appearance. The color layer 13 may be formed by vacuum deposition methods such as magnetron sputtering, vacuum evaporation, or arc ion plating. The color layer 13 may have a thickness of about 0.7 micrometers (μm)-1.3 μm.

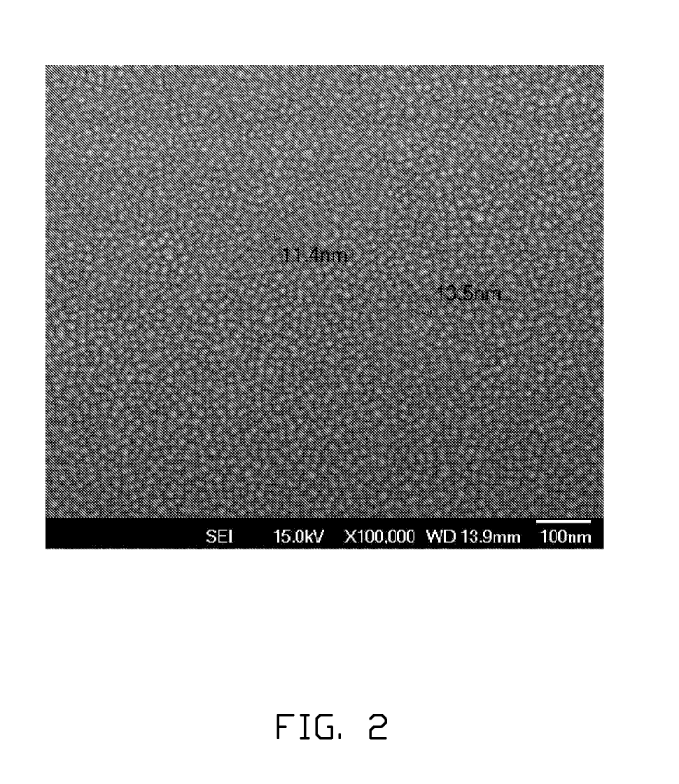

The ceramic layer 15 substantially comprises a substance M, elemental oxygen (O), and elemental nitrogen (N), wherein M can be elemental Al or elemental Zn. The atomic ratio of the substance M, elemental O, and elemental N is about (0.9-1.1):(0.9-1.1):(0.9-1.1), and is selected as 1:1:1 in this exemplary embodiment. Referring to FIG. 2, the ceramic layer 15 is composed of nano-sized grains having an average size of about 10 nanometer (nm)-15 nm, with very small spaces between the grains. The ceramic layer 15 is homogeneous and dense. The ceramic layer 15 has a surface roughness (Ra) of about 15 nm-100 nm.

The ceramic layer 15 is transparent and colorless and has a high glossiness. Thus, the ceramic layer 15 is presented with a glazed appearance. The thickness of the ceramic layer 15 may be about 20 nm-300 nm, and preferably 20 nm-100 nm to achieve a transparent appearance. The ceramic layer 15 may be formed by vacuum deposition methods such as magnetron sputtering, vacuum evaporation or arc ion plating.

The 60 degree specula gloss (Gs 60°) of the layer formed by the ceramic layer 15 in combination with the color layer 13 is about 83-90. The ceramic layer 15 combining the color layer 13 has an L* value between about 85 to about 90, an a* value between about −0.5 to about 0.5, and an b* value between about −2.0 to about 3.0 in the CIE LAB.

The ceramic layer 13 combining the color layer 15 causes the coated article 10 to present a high level of whiteness, brightness and translucent appearance like bone china.

An exemplary method for manufacturing the coated article 10 is described as follows. In this exemplary method, both the color layer 13 and the ceramic layer 15 are formed by magnetron sputtering. The exemplary method may include the following steps:

Providing a substrate 11. The substrate 11 may be made of metal, such as stain steel, Al, Al alloy, Mg, or Mg alloy. The substrate 11 may also be made of non-metal material, such as plastic.

Pretreating the substrate 11 by washing with a solution (e.g., alcohol or acetone) in an ultrasonic cleaner to remove impurities and contaminations, such as grease, or dirt. The substrate 11 is then dried.

The substrate 11 is then cleaned by argon plasma cleaning.

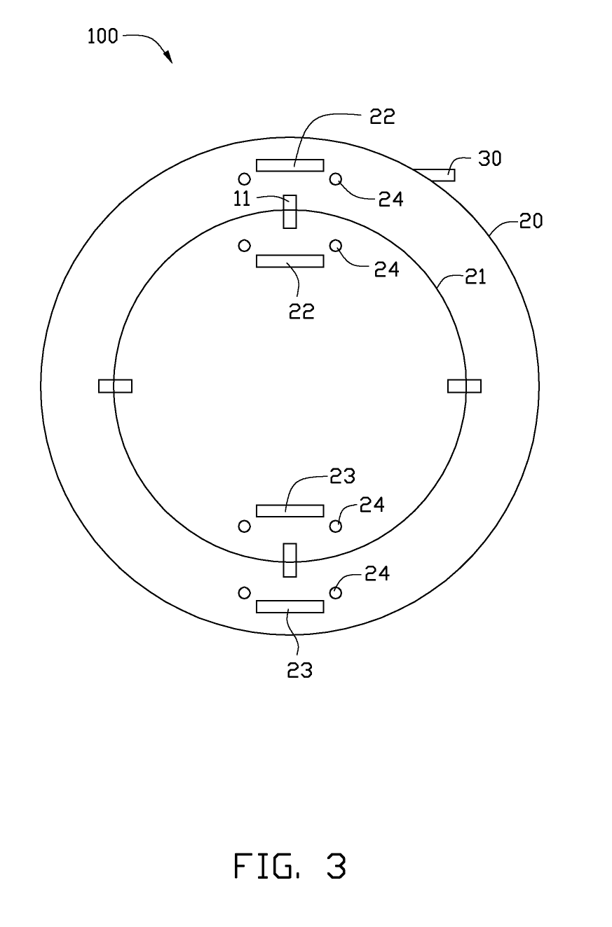

Providing a vacuum sputtering machine 100. Referring to FIG. 3, the vacuum sputtering machine 100 includes a vacuum chamber 20 and a vacuum pump 30 connected to the vacuum chamber 20. The vacuum pump 30 is used to evacuate the vacuum chamber 20. The vacuum sputtering machine 100 further includes a rotating bracket 21, two first targets 22, two second targets 23, and a plurality of gas inlets 24. The rotating bracket 21 rotates the substrate 11 in the vacuum chamber 20 relative to the first targets 22 and the second targets 23. The two first targets 22 face each other, and are located on opposite sides of the rotating bracket 21, and the same arrangement applies to the two second targets 23. The first targets 22 are made of a material selected from the group consisting of Al, Al alloy, Zn and Zn alloy. The second targets 23 are made of Al or Zn. If the first targets 22 are made of Al alloy or Zn alloy, the mass percentage of the elemental Al or elemental Zn is about 85%-90%.

Cleaning the substrate 11 by argon plasma. The substrate 11 is retained on the rotating bracket 21. The vacuum level inside the vacuum chamber 20 is maintained at about 3×10⁻³ Pa-8×10⁻³ Pa. Argon gas is fed into the vacuum chamber 20 at a flow rate about 100 Standard Cubic Centimeters per Minute (sccm) to about 400 sccm from the gas inlets 24. A bias voltage applied to the substrate 11 may be between about −200 volts (V) and about −500 V. Argon gas is ionized to plasma. The plasma strikes against and cleans the surface. Plasma cleaning the substrate 11 may take about 3 minutes (min) to about 20 min.

The color layer 13 is deposited on the substrate 11 by magnetron sputtering. The temperature in the vacuum chamber 20 is set between about 20° C. and about 200° C. Argon may be used as a working gas and is fed into the vacuum chamber 20 at a flow rate from about 100 sccm to about 300 sccm. A bias voltage of about −100 V to about −300 V is applied to substrate 11. About 8 kW-12 kW of power is applied to first targets 22, depositing the color layer 13 on the substrate 11. Depositing the color layer may take about 10 min-30 min.

Magnetron sputtering the ceramic layer 15 on the color layer 13. The first targets 22 are switched off. The internal temperature of the vacuum chamber 20 is maintained at about 20° C. to about 200° C. Argon may be used as a working gas and is injected into the vacuum chamber 20 at a flow rate from about 100 sccm to about 300 sccm. Nitrogen (N₂) and oxygen (O₂) may be used as reaction gases. The nitrogen may have a flow rate of about 80 sccm-300 sccm, and the oxygen may have a flow rate of about 50 sccm-200 sccm. A bias voltage of about −100 V to about −300 V is applied to the substrate 11. About 8 kW-12 kW of power is applied to the second targets 23, depositing the ceramic layer 15 on the color layer 13. Depositing of the ceramic layer 15 may take about 3 min-20 min.

It is to be understood that the color layer 13 and the ceramic layer 15 can also be formed by vacuum evaporation or arc ion plating.

The coated article 10 manufactured by the exemplary method presents a bone china-like appearance. The method described herein is simpler, and can have higher productivity and lower cost compared to the typical method of bone china. The coated article 10 may be widely used in many fields (e.g., electronic products, automobiles and houseware articles), as the coated article 10 can be mass-produced on an industrial scale. Additionally, the substrate 11 can be made of stainless steel, Al, Al alloy, Mg, Mg alloy or plastic can improve the toughness of the coated article 10. Furthermore, when the substrate 11 is made of light metal (e.g., Al, Al alloy, Mg and Mg alloy) or plastic can cause the coated article 10 more lightly relative to the typical bone china products.

Specific examples of making the coated article 10 are described as following. The ultrasonic cleaning in these specific examples may be substantially the same as described above so it is not described here again. The specific examples mainly emphasize the different process parameters of making the coated article 10.

### Example 1

The substrate 11 is made of 304 type stainless steel. The vacuum level inside the vacuum chamber 20 is maintained at about 3×10⁻³ Pa.

Plasma cleaning the substrate 11: the flow rate of argon is 100 sccm; a bias voltage of −300 V is applied to the substrate 11; plasma cleaning of the substrate 11 takes 10 min.

Sputtering to form color layer 13 on the substrate 11: the first targets 22 are aluminum; the flow rate of argon is 150 sccm; the internal temperature of the vacuum chamber 20 is 80° C.; a bias voltage of −100 V is applied to the substrate 11; about 8 kW of power is applied to the first targets 22; sputtering of the color layer 13 takes 10 min.

Sputtering to form the ceramic layer 15 on the color layer 13: the second targets 23 are aluminum; the flow rate of argon is 150 sccm, the flow rate of nitrogen is 80 sccm, the flow rate of oxygen is 50 sccm; the internal temperature of the vacuum chamber 20 is 80° C.; a bias voltage of −100 V is applied to the substrate 11; about 10 kW of power is applied to the second targets 23; sputtering of the ceramic layer 15 takes 5 min.

### Example 2

The substrate 11 is made of 3003 type Al alloy. The vacuum level inside the vacuum chamber 20 is maintained at about 3×10⁻³ Pa.

Plasma cleaning the substrate 11: the flow rate of argon is 120 sccm; a bias voltage of −300 V is applied to the substrate 11; plasma cleaning of the substrate 11 takes 8 min.

Sputtering to form color layer 13 on the substrate 11: the first targets 22 are aluminum; the flow rate of argon is 180 sccm; the internal temperature of the vacuum chamber 20 is 90° C.; a bias voltage of −120 V is applied to the substrate 11; about 9 kW of power is applied to the first targets 22; sputtering of the color layer 13 takes 20 min.

Sputtering to form the ceramic layer 15 on the color layer 13: the second targets 23 are zinc; the flow rate of argon is 180 sccm, the flow rate of nitrogen is 90 sccm, the flow rate of oxygen is 60 sccm; the internal temperature of the vacuum chamber 20 is 90° C.; a bias voltage of −120 V is applied to the substrate 11; about 9 kW of power is applied to the second targets 23; sputtering of the ceramic layer 15 takes 8 min.

### Example 3

The substrate 11 is made of 5252 type Al alloy. The vacuum level inside the vacuum chamber 20 is maintained at about 3×10⁻³ Pa.

Plasma cleaning the substrate 11: the flow rate of argon is 150 sccm; a bias voltage of −300 V is applied to the substrate 11; plasma cleaning of the substrate 11 takes 5 min.

Sputtering to form color layer 13 on the substrate 11: the first targets 22 are zinc; the flow rate of argon is 280 sccm; the internal temperature of the vacuum chamber 20 is 100° C.; a bias voltage of −150 V is applied to the substrate 11; about 10 kW of power is applied to the first targets 22; sputtering of the color layer 13 takes 30 min.

Sputtering to form the ceramic layer 15 on the color layer 13: the second targets 23 are aluminum; the flow rate of argon is 200 sccm, the flow rate of nitrogen is 150 sccm, the flow rate of oxygen is 100 sccm; the internal temperature of the vacuum chamber 20 is 100° C.; a bias voltage of −150 V is applied to the substrate 11; about 10 kW of power is applied to the second targets 23; sputtering of the ceramic layer 15 takes 10 min.

### Results

The coated articles created by example 1-3 have similar bone china-like appearances.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate;
a color layer formed on the substrate, the color layer substantially comprising a material selected from the group consisting of aluminum, aluminum alloy, zinc, and zinc alloy; and
a ceramic layer formed on the color layer, the ceramic layer substantially comprising a substance M, elemental O, and elemental N, wherein M is elemental Al or elemental Zn.

2. The coated article as claimed in claim 1, wherein the atomic ratio of the substance M, elemental O, and elemental N is about (0.9-1.1):(0.9-1.1):(0.9-1.1).

3. The coated article as claimed in claim 2, wherein the atomic ratio of the substance M, elemental O, and elemental N is about 1:1:1.

4. The coated article as claimed in claim 1, wherein the ceramic layer is transparent and colorless.

5. The coated article as claimed in claim 1, wherein the aluminum alloy or zinc alloy, has a mass percentage of about 85%-90% of aluminum or zinc.

6. The coated article as claimed in claim 1, wherein the color layer has an L* value between about 88 to about 93 in the CIE L*a*b* color space.

7. The coated article as claimed in claim 1, wherein the color layer has a thickness of about 0.7 μm-1.3 μm.

8. The coated article as claimed in claim 1, wherein the layer formed by the ceramic layer in combination with the color layer has an L* value between about 85 to about 90, an a* value between about −0.5 to about 0.5, and an b* value between about −2.0 to about 3.0 in the CIE L*a*b* color space.

9. The coated article as claimed in claim 1, wherein the 60 degree specula gloss of the layer formed by the ceramic layer in combination with the color layer is about 83-90.

10. The coated article as claimed in claim 1, wherein the ceramic layer is composed of nano-sized grains having an average size of about 10 nm-15 nm.

11. The coated article as claimed in claim 1, wherein the ceramic layer has a surface roughness of about 15 nm-100 nm.

12. The coated article as claimed in claim 1, wherein the ceramic layer has a thickness of about 20 nm-300 nm.

13. The coated article as claimed in claim 1, wherein the substrate is made of a material selected from the group consisting of stainless steel, aluminum, aluminum alloy, magnesium, magnesium alloy and plastic.

14. A method for manufacturing an article, comprising:
providing a substrate;
forming a color layer on the substrate by vacuum deposition, the color layer substantially comprising a material elected from the group consisting of aluminum, aluminum alloy, zinc, and zinc alloy; and
forming a ceramic layer on the color layer by vacuum deposition, the ceramic layer substantially comprising a substance M, elemental O, and elemental N, wherein M is elemental Al or elemental Zn.

15. The method of claim 14, wherein the color layer is formed by magnetron sputtering, using first targets made of one material selected from the group consisting of Al, Al alloy, Zn and Zn alloy.

16. The method of claim 15, wherein magnetron sputtering of the color layer uses argon at a flow rate of about 100 sccm-300 sccm as a working gas; applies a power of about 8 kW-12 kW to the first targets; applies a bias voltage of about −100 V to about −300 V to the substrate; magnetron sputtering of the color layer is conducted at a temperature of about 20° C.-200° C. and takes about 10 min-30 min.

17. The method of claim 16, wherein magnetron sputtering of the color layer is carried out in a vacuum chamber of a vacuum sputtering machine, the vacuum chamber maintaining internal vacuum level of about 3×10⁻³ Pa-8×10⁻³ Pa.

18. The method of claim 14, wherein the ceramic layer is formed by magnetron sputtering, using second targets made of Al or Zn, and using oxygen and nitrogen as reaction gases.

19. The method of claim 18, wherein magnetron sputtering of the ceramic layer uses argon at a flow rate of about 100 sccm-300 sccm as a working gas, uses the oxygen at a flow rate of about 50 sccm-200 sccm and uses the nitrogen at a flow rate of about 80 sccm-300 sccm; applies a power of about 8 kW-12 kW to the second targets; applies a bias voltage of about −100 V to about −300 V to the substrate; magnetron sputtering of the ceramic layer is conducted at a temperature of about 20° C.-200° C. and takes about 3 min-20 min.

20. The method of claim 19, wherein magnetron sputtering of the ceramic layer is carried out in a vacuum chamber of a vacuum sputtering machine, the vacuum chamber maintaining internal vacuum level of about 3×10⁻³ Pa-8×10⁻³ Pa.
